(19) United States
(12) Patent Application Publication
(10) Pub. No.: US 2007/0049048 A1
(43) Pub. Date: Mar. 1, 2007

(54) Method and apparatus for improving nitrogen profile during plasma nitridation

(76) Inventors: Shahid Rauf, Pflugerville, TX (US); Peter L.G. Ventzek, Austin, TX (US)

Correspondence Address: HAMILTON & TERRILE, LLP, P.O. BOX 203518, AUSTIN, TX, 78720, US

(21) Appl. No.: 11/216,254

(22) Filed: Aug. 31, 2005

(51) Int. Cl. H01L 21/31

(52) U.S. Cl. 438/775; 257/E21.302

(57) ABSTRACT

A semiconductor manufacturing apparatus and process for forming a nitrided dielectric film includes generating a plasma source (44) over a wafer structure (46), where the plasma source (44) includes neutral species (such as nitrogen atoms) and charged species (such as nitrogen ions) that are formed in an inductively coupled plasma reactor. Before the charged species in the plasma (44) can penetrate the wafer structure (46), an electrically connected mesh structure (45, 47) between the plasma source (44) and wafer structure (46) blocks the charged species. In addition or in the alternative, a magnetic field (69) aligned in parallel with the surface of the wafer structure (66) is established in close proximity to the wafer structure (66) in order to trap the charged species. By removing charged species, an improved, narrower nitrogen concentration profile is obtained.

### BACKGROUND OF THE INVENTION

1. Field of the Invention

The present invention is directed in general to the field of semiconductor devices. In one aspect, the present invention relates to the formation a dielectric layer.

2. Description of the Related Art

When transistor gate dielectric layers incorporate nitrogen, the transistor's electrical characteristics (leakage current, short channel effects) are improved since the nitridation increases the dielectric constant, thereby allowing use of thicker films. In addition, nitrogen in the gate dielectric reduces boron penetration to the silicon channel during ion implantation. Early nitridation experiments used thermal techniques to expose dielectric films to various nitrogen containing gases (NO, N₂O, NH₃, N₂) at elevated temperatures. Although thin films can be readily nitrided using thermal means, one major concern with thermal nitridation techniques is that there is considerable amount of nitrogen present near the dielectric/silicon interface, which deteriorates the interfacial properties.

Among the other techniques that have been explored for thin dielectric film nitridation, plasma nitridation has emerged as a promising approach. In plasma nitridation, the dielectric-coated wafer is exposed to an adjacent or remote N₂ plasma for sufficient time that nitrogen gets incorporated into the dielectric layer. Though transistors using the plasma-nitrided dielectric films have superior electrical characteristics and improved robustness, the transistor electrical characteristics are sensitive to the profile of nitrogen within the dielectric layer since nitrogen near the dielectric/silicon interface makes the transistors less reliable, while nitrogen near the dielectric surface reduces leakage current through the dielectric. FIG. 1 depicts the measured nitrogen concentration profiles within conventionally nitrided dielectric layers of differing thicknesses. Profile 12 shows the profile for a base oxide thickness of 13 Angstroms, profile 14 shows the profile for a base oxide thickness of 14 Angstroms, and profile 16 shows the profile for a base oxide thickness of 15 Angstroms. These measurements show that the nitrogen concentration peaks near the dielectric surface and decays into the film. However, the nitrogen concentration near the dielectric/silicon interface can be appreciable. For example, with the profile 12 for a base oxide thickness of 13 Angstroms, the nitrogen concentration near the dielectric/silicon interface is 10.3 percent relative to the peak, while the nitrogen concentration near the dielectric/silicon interface for the 14 Angstrom oxide layer is 9 percent (per profile 14) with respect to the peak and the nitrogen concentration near the dielectric/silicon interface for the 15 Angstrom oxide layer is 8.2 percent (per profile 16) with respect to the peak.

While increasing the plasma source power or nitridation time can increase the nitrogen concentration in the dielectric layer, conventional high density plasma nitridation sources have a high nitridation rate that is difficult to control. In addition, the nitridation rate tapers off as the dielectric surface saturates with nitrogen. While pulsed power sources can make the nitridation rate more manageable, such sources also broaden the nitrogen concentration profile. With the broader nitrogen concentration profiles, there is more nitrogen located near the dielectric/silicon interface, which increases leakage current. Source power impacts nitrogen profile as well. This effect is illustrated in FIG. 2, which shows the effect of plasma power on the measured nitrogen concentration profiles. In particular, profile 13 shows the nitrogen concentration profile for a 350W plasma source, profile 15 shows the nitrogen concentration profile for a 650W plasma source, profile 17 shows the nitrogen concentration profile for a 950W plasma source, and profile 19 shows the nitrogen concentration profile for a 1250W plasma source.

Accordingly, a need exists for a plasma nitridation process and apparatus which provides a manageable and controllable nitridation source. In addition, there is a need for a plasma nitridation process and apparatus that reduces leakage current by optimizing the nitrogen concentration profile in the gate dielectric layers. There is also a need for improved semiconductor processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 depicts SIMS measurements of the effect of initial dielectric thicknesses on nitrogen concentration profile within a dielectric layer;

FIG. 2 depicts SIMS measurements of the effect of plasma source power on nitrogen concentration profile within a dielectric layer;

FIG. 3 depicts a computation of the contributing effects of neutral nitrogen and nitrogen ions on the nitrogen profile within a dielectric layer;

FIG. 4 is a diagrammatic view of a semiconductor device fabrication process chamber for implementing various embodiments of the present invention;

FIG. 5 is a diagrammatic side view of the meshes depicted in FIG. 4;

FIG. 6 is a diagrammatic view of an alternative semiconductor device fabrication process chamber for implementing various embodiments of the present invention; and

FIG. 7 depicts a comparison of a nitrogen concentration profiles for dielectric layers formed with and without ion blocking.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for blocking, filtering or otherwise removing nitrogen ions from a plasma nitridation source so that only atomic nitrogen is absorbed into the surface of a dielectric film. The disclosed techniques may be used to fabricate a semiconductor device having a dielectric layer, such as a gate dielectric in a field effect transistor or a non-volatile memory device or a dielectric in a capacitor. The improved performance resulting from such a process may advantageously be incorporated with CMOS process technology. Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort-might be complex and time-consuming, it would nevertheless be a routine undertaking for those of ordinary skill in the art having the benefit of this disclosure. For example, selected aspects are depicted with reference to simplified drawings in order to avoid limiting or obscuring the present invention. Such descriptions and representations are used by those skilled in the art to describe and convey the substance of their work to others skilled in the art.

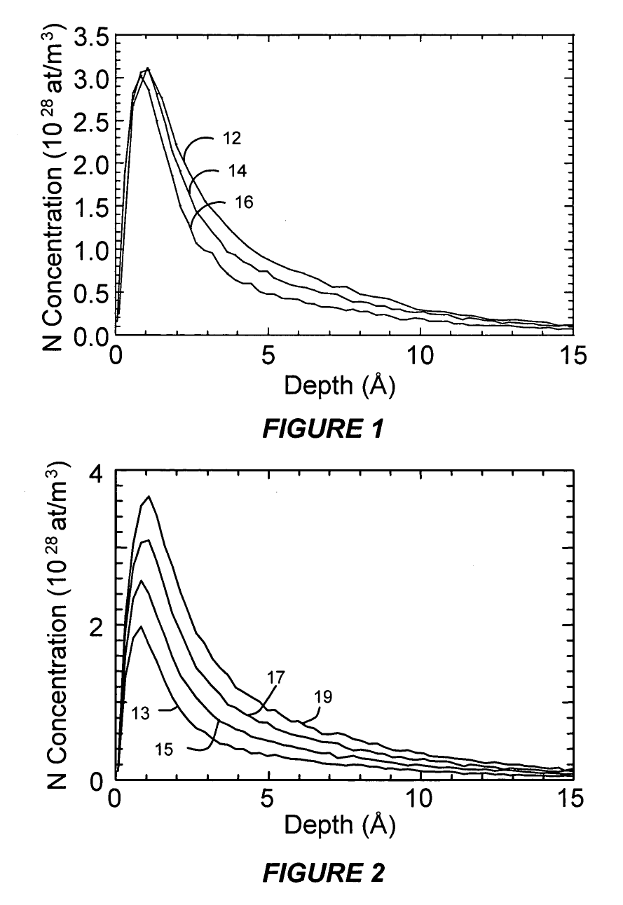

While significant effort has been directed towards the development of the plasma nitridation technology for thin dielectric layer nitridation, relatively little attention has been paid to the underlying physics of the plasma nitridation process. For example, FIGS. 1 and 2 depict SIMS measurements of the nitrogen concentration profiles within a dielectric layer that are produced from conventional plasma nitridation processes. The depicted measurements show that the nitrogen concentration profile within the film peaks near the surface and tapers off towards the SiO₂—Si interface.

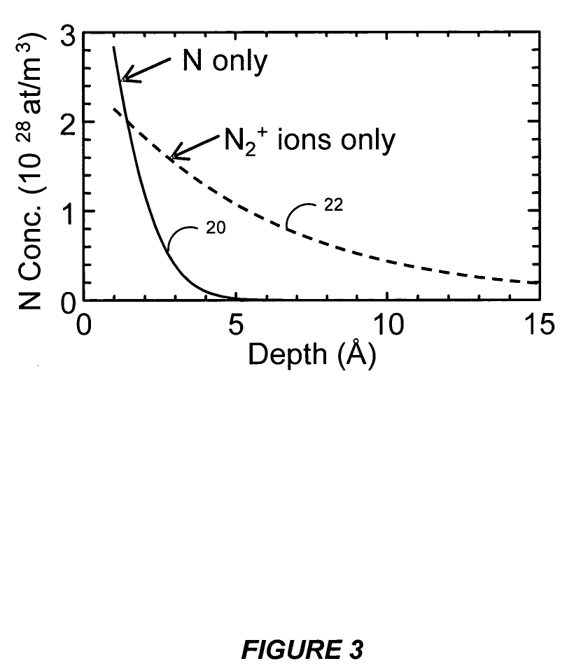

In connection with developing the present invention, it has been determined that nitrogen N₂⁺ ions and atomic nitrogen are the primary species in the N₂ plasma that contribute to nitridation of SiO₂ thin film. FIG. 3 illustrates the separate contributions to the nitrogen concentration profile by the nitrogen atoms and ions by depicting a computation of the contributing effects of neutral nitrogen (profile 20) and nitrogen ions (profile 22) on the nitrogen profile within a dielectric layer. As seen from profile 20, the atomic nitrogen generated by the plasma nitridation source is adsorbed at the surface of the SiO₂ layer, and upon being heated by the hot plasma, the atomic nitrogen diffuses into the SiO₂ layer, resulting in a concentration profile which peaks very near the surface and decays rapidly into the SiO₂ layer. Thus, nitrogen atoms adsorb at the SiO₂ surface and diffuse into the bulk film, so that most nitrogen near the surface is due to these adsorbed N atoms.

The plasma nitridation source also generates nitrogen ions (N₂⁺, N⁺) which enter the SiO₂ layer in an ion implantation-like manner. As shown in profile 22, the ions have higher energy and require more collisions to slow down, and therefore they penetrate more deeply into the SiO₂ layer, resulting in a concentration profile with a smaller peak and a slower decay into the SiO₂ layer. Thus, the ions are responsible for the observed tail in the combined nitrogen concentration profile (e.g., profile 12 in FIG. 1).

As seen from the foregoing, it has been determined that the nitrogen concentration profile from plasma nitridation may be understood to result from the separate contributions of nitrogen ions and atomic nitrogen, and that the nitrogen ions are responsible for broadening of the nitrogen concentration profile. Accordingly, selected embodiments of the present invention improve the electrical characteristics of a transistor by limiting access of N₂⁺ ions to the dielectric surface. The reduced ion access may be accomplished in a variety of ways, including removing, reducing, blocking, filtering, sweeping, magnetizing, impeding, trapping or otherwise preventing nitrogen ions from a plasma nitridation source from reaching the dielectric surface. The filtering or reduction of nitrogen ions substantially narrows the nitrogen concentration profile in the dielectric film, thereby reducing the nitrogen concentration near the dielectric/silicon interface to reduce leakage current and improve reliability.

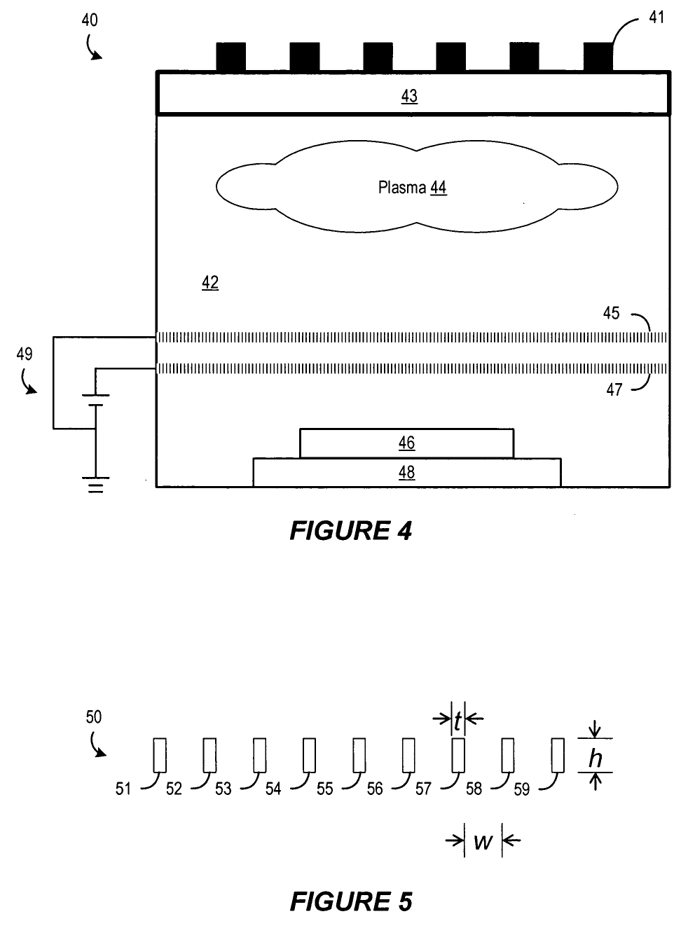

To illustrate one embodiment of the present invention, refer to FIG. 4, which diagrammatically illustrates a fabrication process chamber 40 for establishing plasma processing environment 42. As will be appreciated, a variety of different fabrication process chamber types can be used, including conventional inductively coupled plasma (ICP) reactors, pulsed inductively coupled plasma reactors, electron cyclotron resonance reactors, helicon reactors, surface wave discharges, laser ignited devices, magnetron reactors, target sputtering reactors and the like. For example, the fabrication process chamber 40 may be implemented as an inductively coupled plasma reactor which uses coils 41 to generate a glow-discharge of N₂ plasma 44 from gaseous N₂, an evaporation source, a reactive gas with condensable constituents, or a mixture of reactive gases with condensable constituents and other gases that react with the condensed constituents to form compounds. Alternatively, plasma processing environment 42 may be provided with a sputtering target 43 which is formed with material that is selected to be the source material for the plasma source 44 in the plasma reactor. However generated, the plasma chemical mechanism for the N₂ plasma 44 may include ion-molecule and other heavy particle reactions, electron impact neutral dissociation, (dissociative) ionization, and excitation reactions for N₂ and other neutral species.

In the plasma processing environment 42, a substrate or other semiconductor wafer or structure 46 is mounted on a tray or other delivery mechanism 48 provided in the plasma processing environment 42. In an example embodiment, the semiconductor structure 46 may be a semiconductor substrate (e.g., bulk silicon substrate, single crystalline silicon (doped or undoped), a silicon-on-insulator (SOI) substrate or any semiconductor material including, for example, Si, SiC, SiGe, SiGeC, Ge, GaAs, InAs, InP as well as other Group III-IV compound semiconductors or any combination thereof) on which is formed a dielectric layer (e.g., silicon dioxide, oxynitride, metal-oxide, nitride, any high-k dielectric, etc.), though the semiconductor structure may also be a semiconductor structure on which a layer of photoresist is formed, a (partially formed) integrated circuit structure to be cleaned or plasma oxidized. The substrate 46 is made the cathode of a glow discharge process by, for example, supplying RF power to the coils 41 in a pulsed manner while DC or RF power may be applied to the substrate 46. Alternatively, DC power from a target power source (not shown) may be supplied to the sputtering target 43, while RF bias power (not shown) is applied to the substrate 46 via the delivery mechanism 48.

It will be appreciated that the relative placement of the plasma source 44 and wafer/substrate 46 can improve the plasma process. For example, by providing a plasma source 44 that is proximately adjacent to the wafer/substrate 46, the plasma source species may be controllably transported to the wafer/substrate surface, as compared with remote plasma sources.

The plasma processing environment 42 also includes one or more selective barrier structures positioned between the nitrogen plasma source 44 and the wafer/substrate 46 to provide an electrical barrier to inhibit or prevent the charged species (e.g., nitrogen ions) from reaching the wafer/substrate 46, while allowing neutral species (e.g., nitrogen atoms) to reach the wafer/substrate 46. Examples of selective barrier structures include a woven mesh, colander, sieve, grid, plate with holes or other mesh structures 45, 47 that are formed of a conductive material, such as a metal. Each mesh is positioned between the plasma source 44 and the substrate 46. Each mesh structure may be electrically grounded or biased, though in a selected embodiment, a differential voltage supply 49 is connected between first and second mesh structures 45, 47 so that the first mesh 45 is electrically grounded and the second mesh 47 is positively biased. While the relative bias between the meshes 45, 47 may be reversed, a negatively biased first or upper mesh 45 allows nitrogen atoms and ions from the plasma 44 to pass into the space between the first and second meshes 45, 47, but the plasma 44 is otherwise confined by the sheath above the mesh 45. As for the second or lower mesh, the electrical field created from the positively biased second mesh 47 acts to repel nitrogen ions so that the ions to not penetrate the second mesh, but holes or openings in the second mesh 46 that are smaller than the plasma sheath permit nitrogen atoms to penetrate the second mesh 47.

In operation, the plasma processing environment 42 in the chamber 40 is established at a predetermined state by, for example, using a pumping system to provide and maintain a gas (e.g., nitrogen or argon) at a predetermined pressure (e.g., between 2 and 15 milliTorr, or below 20 milliTorr). By supplying power to the chamber 40, a glow-discharge of plasma 44 is induced or created in the chamber environment 42. The way in which power is supplied to the chamber will affect how the constituent components of the plasma 44 are generated and maintained. For example, with N₂ plasma, a steady power source applied to the coils 46 will generate a combination of neutral species (such as N₂, N, N₂(v), N₂* and/or N*) and charged species (such as N₂⁺ and/or N⁺ ions). As power is increased, the neutral and charged species generation also increases. By pulsing the power supply provided to the coils 41, the nitrogen atom density in the plasma 44 does not vary substantially. In contrast, the electron and ion densities in the plasma 44 can change appreciably over the course of a pulsed power source. For example, the N₂⁺ ion density is lower when the source power is turned off, but rapidly increases as the source power is turned on. By increasing the source power more slowly when the power source is turned on, the rate of N₂⁺ ion flux may be reduced. For both the atomic nitrogen and the nitrogen ions, the peak density moves from below the coils 41 toward the center of the chamber 40 as the source power is turned off.

Thus, the power supply may be a pulsed power supply having low frequency or radio frequency cycles that is applied to the coils 41 (e.g., with a 20% duty cycle) to generate or control the N₂ plasma 44 within plasma processing environment 42. Alternatively, the power supply may be a DC power source that is supplied to the sputtering target 43, or any desired power source supply. In the case of a sputtering reactor, the sputtering target 43 is bombarded by accelerated plasma ions to dislodge and eject target material from the sputtering target 43 in the form of a glow-discharge plasma 44.

Regardless of how power is supplied to the chamber 40, the discharge plasma 44 that is generated includes neutral particles and ions, some of which move across the plasma processing environment 42 toward the substrate 46. The movement can be caused by diffusion, gas flow or electric field mechanisms, depending on the type of species. For example, atomic nitrogen will be transported by a diffusion mechanism, while nitrogen ions are moved under the influence of an electric field that is established when the power source is turned on. In particular, by producing an electric field that is substantially perpendicular to the exposed surface of the substrate 46, ions in the plasma 44 accelerate across plasma processing environment 42 toward the substrate 46. However, before the plasma ions can reach the substrate 46, they are intercepted by one or more electrically grounded or biased mesh structures 45, 47 positioned between the plasma source 44 and the substrate 46. Through appropriate design and placement of the mesh structure(s), the nitrogen ions will be electrically blocked, while neutral nitrogen particles will flow to the substrate 46 almost unimpeded.

FIG. 5 shows a more detailed side view of a mesh structure implementation of the electrical barrier in accordance with various embodiments of the present invention. In the depicted example, a first mesh structure 50 is constructed from a plurality of mesh conductor elements 51-59. In a selected embodiment, the horizontal spacing (w) between individual mesh conductor elements or wires (e.g., 57, 58) is smaller than the plasma sheath width for the plasma 44 (<1 mm in high density plasmas), while the mesh height (h) and thickness (t) for each mesh conductor element/wire are less than the mean free path of neutral particles (e.g., approximately 4 cm at 7.5 mTorr for atomic nitrogen). By positioning such a mesh structure 50 in proximity to the wafer/substrate, the neutral nitrogen species will flow to the wafer almost unimpeded.

In accordance with selected embodiments of the present invention, ion blocking or reduction can be improved further by including at least a second mesh structure 47 in the chamber 40, as illustrated in FIG. 4. The first and second mesh structures 45, 47 may be positioned in relative alignment with one another and in close proximity to the wafer substrate 46, though the advantages of the present invention may also be obtained regardless of the alignment and position of the mesh structures 45, 47, so long as they are positioned substantially between the plasma source 44 (e.g., the position of the plasma's peak density) and the wafer/substrate 46. When two or more mesh structures 45, 47 are used, structures are electrically biased with respect to one another by a differential voltage supply 49 (as depicted in FIG. 4).

As a result of using one or more mesh structures to block or filter ions, the nitrogen ions will not contribute to nitridation of the wafer 46, and only neutral species will contribute to plasma nitridation of the wafer 46. When the wafer 46 is a dielectric layer formed on a silicon substrate, the ion blocking results in the dielectric's nitrogen concentration profile being much narrower so that there is less nitrogen near the silicon/dielectric interface, but high levels of nitrogen near the dielectric surface.

An additional benefit from removing the ions that contribute nitridation is a decrease in the nitridation rate at the substrate 46. With a lower nitridation rate, the need to pulse the power supply is reduced or eliminated.

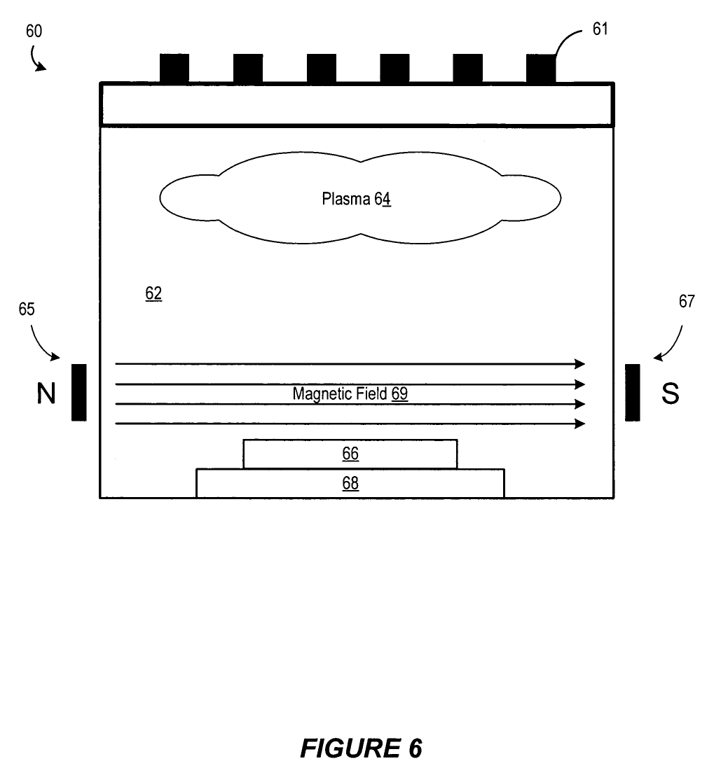

The reduction or removal of plasma ions from the wafer/substrate may be achieved in other ways and still obtain one or more of the benefits of the present invention. For example, FIG. 6 depicts a diagrammatic view of an alternative semiconductor device fabrication process chamber 60 for implementing various embodiments of the present invention to reduce or block ion implantation effects from plasma processing. In the plasma processing environment 62 of the depicted chamber 60, a substrate or other semiconductor wafer or structure 66 is mounted on a tray or other delivery mechanism 68, and coils 61 are also provided for generating a plasma source 64 (e.g., N₂ plasma). The semiconductor structure 66 may be a semiconductor substrate (e.g., p-type silicon wafers) on which is formed a dielectric layer (e.g., a high-k dielectric or a layer of thermally grown SiO₂), or any other partially completed integrated circuit structure. To limit ion access to the wafer/substrate 66, a magnetic field 69 is established near and substantially parallel (or non-intersecting) to the exposed surface of the substrate 46. The magnetic field 69 effectively traps charged particles from the plasma source 64 so that some or all of the charged particles do not reach the wafer/substrate 66.

As will be appreciated, the alignment of the magnetic field 69 in substantially parallel relationship with the wafer/substrate 66 helps prevent ions from reaching the wafer/substrate 66. However, in accordance with alternative embodiments of the present invention, any magnetic field alignment may be used, so long as the magnetic field lines do not direct ions to the wafer/substrate 66.

In the example depicted in FIG. 6, the magnetic field 69 is established with a first magnet 65 and a second magnet 67 that are positioned peripherally to the chamber 60. If the strength of the magnetic field 69 established by the magnets 65, 67 is large enough, the positive ions are trapped and prevented from reaching the substrate 66. On the other hand, weaker magnetic fields may be adequate to confine electrons, but will not prevent ions from reaching the wafer/substrate 66. For example, a magnetic field strength B that is greater than 1000 Gauss will make the nitrogen ion gyration radius around the magnetic field lines less than 1 mm. Since the magnetic field 69 acts to trap the nitrogen ions but not the neutral species, only neutral nitrogen species will flow unimpeded to the wafer/substrate 66.

Additional processing steps may be used to complete the fabrication of the substrate or other semiconductor wafer or structure 66 into functioning transistors. As examples, one or more sacrificial oxide formation, stripping, isolation region formation, gate formation, extension implant, halo implant, spacer formation, source/drain implant, and polishing steps may be performed, along with conventional backend processing, typically including formation of multiple levels of interconnect that are used to connect the transistors in a desired manner to achieve the desired functionality. Thus, the specific sequence of steps used to complete the fabrication of the substrate/wafer 66 may vary, depending on the process and/or design requirements. Also, other semiconductor device levels may be formed underneath or in the wafer/substrate 66.

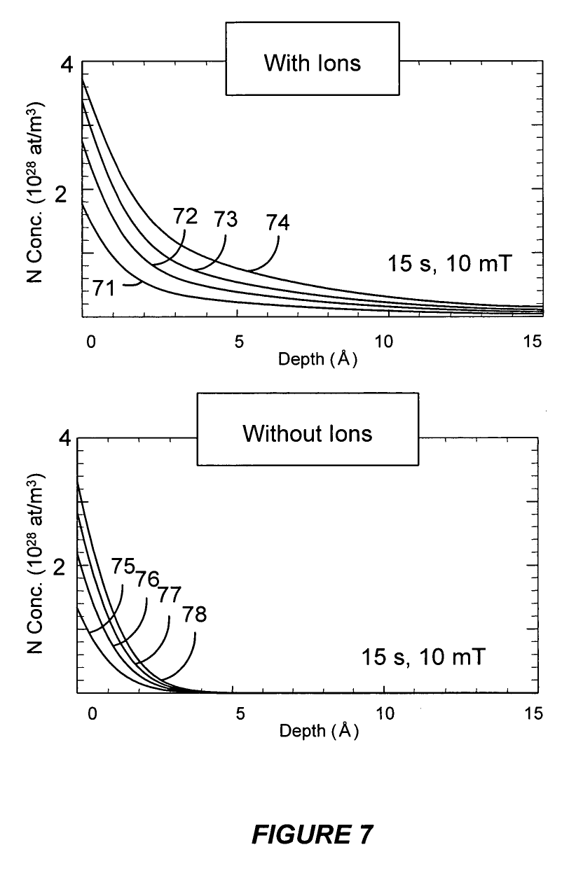

Turning now to FIG. 7, there is depicted a simulated comparison of a nitrogen concentration profiles for a dielectric layer where positive ions are not blocked from reaching the wafer (profiles 71-74) and for a dielectric layer where positive ions are blocked from reaching the wafer (profiles 75-78). Profile 71 is the simulated nitrogen concentration profile without filtering from a 350W plasma source (at 15 s, 10 mT), profile 72 is the simulated nitrogen concentration profile without filtering from a 650W plasma source (at 15 s, 10 mT), profile 73 is the simulated nitrogen concentration profile without filtering from a 950W plasma source (at 15 s, 10 mT), and profile 74 is the simulated nitrogen concentration profile without filtering from a 1250W plasma source (at 15 s, 10 mT). In contrast, profile 75 is the simulated nitrogen concentration profile with ion filtering from a 350W plasma source (at 15 s, 10 mT), profile 76 is the simulated nitrogen concentration profile with ion filtering from a 650W plasma source (at 15 s, 10 mT), profile 77 is the simulated nitrogen concentration profile with ion filtering from a 950W plasma source (at 15 s, 10 mT), and profile 78 is the simulated nitrogen concentration profile with ion filtering from a 1250W plasma source (at 15 s, 10 mT). The simulated profile comparison shows that the ion-blocked nitrogen concentration profile 71-74 is much narrower and smaller than the no-blocking profile 75-78. As a result, there is a lower nitridation rate, which means that pulsed plasma power sources may not be required. In addition, the narrower profile means that transistor devices using such ion-blocked dielectric layers as gate dielectrics have reduced leakage current because there is less nitrogen near the dielectric/substrate interface.

In one form, there is provided herein a method for thin film plasma nitridation which results in optimized nitrogen concentration profiles and lower nitridation rates. Under the method, a nitrogen plasma source is generated proximately adjacent to a wafer structure, which may be a dielectric layer or photoresist layer formed over a semiconductor substrate. The nitrogen plasma source includes neutral species (such as N₂, N, N₂(v), N₂* and/or N*) and charged species (such as N₂⁺ and/or N⁺ ions), and may be formed by generating a pulsed inductively coupled N₂ plasma. The nitrogen concentration profile for the dielectric film is narrowed by preventing some or all of the charged species from the plasma source from reaching the wafer structure while allowing the neutral species to be absorbed into the wafer structure. Diffusion of charged species to the wafer structure may be controlled or prevented by placing one or more mesh structure between the nitrogen plasma source and the wafer structure, where each mesh structure is electrically connected to a predetermined voltage (such as ground or a bias voltage). In addition or in the alternative, diffusion of charged species is controlled with a magnetic field that is formed adjacent to the wafer structure having magnetic field lines that are substantially aligned in parallel with the exposed surface of the wafer structure.

In another form, a semiconductor manufacturing apparatus and methodology are provided for forming a nitrided film. The apparatus and method use a fabrication chamber having a plasma treatment region for treating a wafer structure on which a thin film (e.g., dielectric film). A gas control system attached to or included in the chamber introduces a nitrogen or a nitrogen-containing compound gas into the fabrication chamber at a controlled gas pressure, and a coil disposed along an outer periphery of the fabrication chamber energizes the gas to generate a glow-discharge of nitrogen plasma which includes nitrogen atoms and ions. To prevent some or all of the nitrogen ions from reaching the wafer structure while atomic nitrogen is absorbed into the wafer structure, a magnetic field generator is provided for generating magnetic field lines in close proximity to and parallel to the wafer structure. In addition or in the alternative, nitrogen ions are prevented from reaching the wafer structure by positioning a one or more mesh structures in the fabrication chamber substantially between the nitrogen plasma and the wafer structure. The mesh(es) are electrically connected and biased with respect to each other. By configuring the mesh conductor elements to be horizontally spaced apart by distance that is smaller than a sheath width associated with the glow-discharge of nitrogen plasma, nitrogen ions are blocked and nitrogen atoms are able to reach the wafer structure without substantial impediment. Selective blocking of the charged particles is also promoted by configuring the mesh conductor elements so that each element has a height and thickness that is less than the mean free path of neutral particles.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. For example, the ion blocking methodology of the present invention may be applied in areas other than incorporating nitride in a gate dielectric layer. For example, ion blocking techniques may be used as part of a photoresist trimming process in order to reduce vertical resist loss caused by implanted ions. The techniques may also be used with other plasma processes, such as plasma oxidation, plasma-enhanced CVD, plasma anodization, plasma polymerization, plasma reduction or cleaning, microwave ECR plasma CVD, cathodic arc deposition, etc. In addition, ion blocking may be used with halogenation processes. Essentially, the present invention can be used with any plasma process in which ions or other charged species may be advantageously filtered, removed or blocked. In addition, the invention is not limited to any particular type of integrated circuit described herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A plasma nitridation method, comprising:
providing a wafer structure;
generating a nitrogen plasma source proximately adjacent to the wafer structure, said nitrogen plasma source comprising neutral species and charged species; and
preventing substantially all charged species from reaching the wafer structure while absorbing the neutral species into an exposed surface of the wafer structure.

2. The method of claim 1, wherein the neutral species comprise nitrogen atoms and the charged species comprise nitrogen ions.

3. The method of claim 2, wherein the neutral species comprise N₂, N, N₂(v), N₂* and/or N*.

4. The method of claim 1, wherein the charged species comprise N₂⁺ and/or N⁺ ions.

5. The method of claim 1, wherein the wafer structure comprises a dielectric layer formed over a semiconductor substrate.

6. The method of claim 1, wherein the wafer structure comprises a photoresist layer formed over a partially formed integrated circuit structure.

7. The method of claim 1, where the step of generating a nitrogen plasma source comprises generating an inductively coupled N₂ plasma.

8. The method of claim 1, where the step of preventing substantially all charged species from reaching the wafer structure comprises providing a selective barrier structure between the nitrogen plasma source and the wafer structure to provide an electrical barrier to prevent the charged species from reaching the wafer structure.

9. The method of claim 8, where the selective barrier structure comprises two mesh structures, each of which is electrically connected to a different predetermined voltage.

10. The method of claim 1, where the step of preventing substantially all charged species from reaching the wafer structure comprises providing a magnetic field adjacent to the wafer structure having magnetic field lines that are substantially aligned in parallel with the exposed surface of the wafer structure.

11. A semiconductor manufacturing apparatus for forming a nitrided film, comprising:
a fabrication chamber comprising a plasma treatment region for treating a wafer structure;
a gas control system for introducing a nitrogen or a nitrogen-containing compound gas and controlling a gas pressure in the fabrication chamber;
a coil for generating a nitrogen plasma comprising atomic nitrogen and nitrogen ions; and
means for inhibiting nitrogen ions from reaching the wafer structure while absorbing the atomic nitrogen into an exposed surface of the wafer structure.

12. The apparatus of claim 11, where the means for inhibiting substantially all nitrogen ions from reaching the wafer structure comprises magnetic field generator for generating a magnetic field that is parallel to the wafer structure.

13. The apparatus of claim 11, where the means for inhibiting substantially all nitrogen ions from reaching the wafer structure comprises an electrical barrier positioned in the fabrication chamber substantially between the nitrogen plasma and the wafer structure.

14. The apparatus of claim 13, where the electrical barrier comprises a plurality of conductor elements configured in a grid, where the conductor elements are horizontally spaced apart by distance that is smaller than a sheath width associated with a glow-discharge for the nitrogen plasma.

15. The apparatus of claim 13, where the electrical barrier comprises a plurality of conductor elements configured in a mesh, where each conductor element has a height and thickness that are less than the mean free path of neutral particles.

16. The apparatus of claim 13, where the electrical barrier comprises a plurality of conductor elements configured to block nitrogen ions and to pass atomic nitrogen without substantial impediment.

17. A method of nitriding a dielectric layer, comprising:
placing a semiconductor structure in a chamber, where the semiconductor structure comprises a dielectric layer formed over a substrate;
generating a nitrogen plasma over the dielectric layer, said nitrogen plasma comprising nitrogen atoms and nitrogen ions; and
blocking nitrogen ions from reaching the dielectric layer while allowing the nitrogen atoms to be absorbed into dielectric layer.

18. The method of claim 17, where one or more mesh structures placed between the nitrogen plasma and the semiconductor structure are used to block the nitrogen ions from reaching the dielectric layer.

19. The method of claim 17, where a magnetic field placed between the nitrogen plasma and the semiconductor structure is used to block the nitrogen ions from reaching the dielectric layer.

20. The method of claim 17, wherein the nitrogen plasma is generated with an inductively coupled plasma reactor, a pulsed inductively coupled plasma reactor, an electron cyclotron resonance reactor, a helicon reactor, a surface wave discharger, a laser ignited device, a magnetron reactor or a target sputtering reactor.
